(19) United States
(12) Patent Application Publication
(10) Pub. No.: US 2019/0326232 A1
(43) Pub. Date: Oct. 24, 2019

(54) RECEIVER AND TRANSMITTER CHIPS PACKAGING STRUCTURE AND AUTOMOTIVE RADAR DETECTOR DEVICE USING SAME

(71) Applicants: Wei-Cheng Lin, Zhubei City (TW); Shih-Hsiu Tseng, Zhubei City (TW); Chien-Jen Hsiao, Zhubei City (TW)

(72) Inventors: Wei-Cheng Lin, Zhubei City (TW); Shih-Hsiu Tseng, Zhubei City (TW); Chien-Jen Hsiao, Zhubei City (TW)

(21) Appl. No.: 15/959,301

(22) Filed: Apr. 23, 2018

(51) Int. Cl. H01L 23/66; G01S 13/93; H01Q 23/00; H01L 21/56; H01L 23/00; H01L 23/31; H01L 25/16

(52) U.S. Cl. CPC H01L 23/66; H01L 2924/01029; H01Q 23/00; H01L 21/56; H01L 24/17; H01L 24/09; H01L 24/49; H01L 23/3107; H01L 25/16; H01L 2224/02379; H01L 2924/01079; H01L 2223/6677; G01S 2013/9321; H01L 2224/0233; G01S 2013/9332; G01S 2013/9346; G01S 13/931

(57) ABSTRACT

A receiver and transmitter chips packaging structure and an automotive radar detector device using same are disclosed. The receiver/transmitter chips packaging structure includes a redistribution layer, a chip set and a molded encapsulation layer. The chip set includes a receiver chip, a transmitter chip and a radio-frequency (RF) processing chip arranged on one side of redistribution layer. The molded encapsulation layer covers the side of the redistribution layer having the receiver, transmitter and RF processing chips arranged thereon and accordingly, enclosed the chip set therein. And, the RF processing chip is electrically connected to the receiver chip and the transmitter chip via a plurality of conductive lines embedded in the redistribution layer.

### FIELD OF THE INVENTION

The present invention relates to a receiver and transmitter chips packaging structure, and more particularly to a receiver and transmitter chips packaging structure that enables upgraded transmission efficiency and increased chip performance. The present invention also relates to an automotive radar detector device that uses the receiver and transmitter chips packaging structure.

### BACKGROUND OF THE INVENTION

The quick development of scientific technologies brings largely upgraded manufacturing techniques to the products having close relation to people's daily life. In particular, the maturity of the semiconductor techniques has enabled the emergence and evolution of new automotive electronic products and accordingly, cars using these novel products. The currently available cars are equipped with many creative technological products and therefore not only enable people to move to different places but also provide drivers and passengers with more safety protections, from the already-known anti-theft systems and parking assistance radars to the newly developed obstacles/pedestrians detection systems, around view monitor systems and autopilot systems. All these car-related technologies can advantageously increase the safety in driving.

The commonly seen car-related safety protection systems, for example the adaptive cruise control systems, blind-spot detection systems, auto-brake systems, front/rear collision warning systems and lane departure detection systems, usually use a microwave FMCW (frequency-modulation continuous-wave) radar system to detect a target object. More specifically, the radar system transmits a millimeter-wave signal and receives a signal reflected from a target object; and further calculates the speed, angular position and distance of the target object relative to radar system. A conventional radar system includes a receiver module, a transmitter module, a voltage-controlled oscillator and a controller. The receiver module, the transmitter module, the voltage-controlled oscillator and the controller are independent and separate elements, and the chips for these elements are respectively independently mounted on a circuit board in each of the elements. For instance, a receiver chip is mounted on a circuit board in the receiver module, a transmitter chip is mounted on a circuit board in the transmitter module, and a voltage-controlled oscillator chip is mounted on a circuit board of the voltage-controlled oscillator. Further, to enable convenient production, the radar system manufacturers would integrate the required antennas, i.e. a receiver antenna and a transmitter antenna, into the receiver chip and the transmitter chip, respectively. However, the above production manner will result in poor transmission efficiency and the transmitter antenna has a transmission power lower than 5 watts to result in the problem of low-power transmission. Moreover, since the chips in different elements, i.e. the receiver chip, the transmitter chip and the voltage-controlled oscillator chip in the receiver module, the transmitter module and the voltage-controlled oscillator, respectively, are fabricated using the same processes, these chips have relatively poor performance.

### SUMMARY OF THE INVENTION

A primary object of the present invention is to provide a receiver and transmitter chips packaging structure as well as an automotive radar detector device using same, which can provide upgraded transmission efficiency.

Another object of the present invention is to provide a receiver and transmitter chips packaging structure as well as an automotive radar detector device using same, which can provide increased transmission power.

A further object of the present invention is to provide a receiver and transmitter chips packaging structure as well as an automotive radar detector device using same, which enable upgraded chip performance by integrally packaging a receiver chip, a transmitter chip and a radio-frequency (RF) processing chip to form one single chip packaging structure.

To achieve the above and other objects, the receiver and transmitter chips packaging structure according to an embodiment of the present invention includes a redistribution layer, a molded encapsulation layer and a chip set. The redistribution layer includes a plurality of conductive lines, a dielectric layer and a plurality of conductive elements. The conductive lines are embedded in the dielectric layer; the dielectric layer has a first side and an opposite second side; and the conductive elements are arranged on the second side of the dielectric layer and are respectively electrically connected to an end of a corresponding one of the conductive lines. The chip set includes a receiver chip, a transmitter chip and a radio-frequency (RF) processing chip. The receiver chip, the transmitter chip and the RF processing chip are arranged on the first side of the dielectric layer and are respectively electrically connected to another end of a corresponding one of the conductive lines; and the RF processing chip is electrically connected to the receiver chip and the transmitter chip via the conductive lines. The molded encapsulation layer is formed on the first side of the dielectric layer to enclose the receiver chip, the transmitter chip and the RF processing chip therein. With the above arrangements, the receiver/transmitter chips packaging structure according to the present invention can provide the effects of upgraded transmission efficiency and chip performance as well as increased transmission power.

To achieve the above and other objects, the automotive radar detector device according to an embodiment of the present invention includes a receiver and transmitter chips packaging structure, a substrate and a control chip. The receiver and transmitter chips packaging structure includes a redistribution layer, a molded encapsulation layer and a chip set. The redistribution layer includes a plurality of conductive lines, a dielectric layer and a plurality of conductive elements. The conductive lines are embedded in the dielectric layer; the dielectric layer has a first side and an opposite second side; and the conductive elements are arranged on the second side of the dielectric layer and are respectively electrically connected to an end of a corresponding one of the conductive lines. The chip set includes a receiver chip, a transmitter chip and a radio-frequency (RF) processing chip. The receiver chip, the transmitter chip and the RF processing chip are arranged on the first side of the dielectric layer and are respectively electrically connected to another end of a corresponding one of the conductive lines; and the RF processing chip is electrically connected to the receiver chip and the transmitter chip via the conductive lines. The molded encapsulation layer is formed on the first side of the dielectric layer to enclose the receiver chip, the transmitter chip and the RF processing chip therein. The substrate has at least one first antenna, at least one second antenna, a plurality of conductive wirings and a plurality of contacts provided thereon to electrically connect to the conductive elements on the redistribution layer. The conductive wirings are embedded in the substrate to electrically connect to the contacts that are formed on one side of the substrate; and the first and the second antenna are provided on one side of the substrate to electrically connect to the receiver chip and the transmitter chip via the conductive wirings and the contacts. The control chip is arranged on one side of the substrate to electrically connect to the receiver chip and the RF processing chip via the conductive wirings and the contacts. With the above arrangements, the automotive radar detector device according to the present invention can provide the effects of upgraded transmission efficiency and chip performance as well as increased transmission power.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of a receiver and transmitter chips packaging structure according to a first embodiment of the present invention;

FIG. 1A is a longitudinal sectional view of FIG. 1;

FIG. 2 is an assembled perspective view of an automotive radar detector device according to a second embodiment of the present invention;

FIG. 2A is a longitudinal sectional view of FIG. 2;

FIG. 3A is a block diagram of the automotive radar detector device according to the second embodiment of the present invention;

FIG. 3B is a block diagram of another possible arrangement of the automotive radar detector device according to the second embodiment of the present invention;

FIG. 4A is an assembled perspective view of an automotive radar detector device according to a third embodiment of the present invention; and

FIG. 4B is a longitudinal sectional view of FIG. 4A.

### DETAILED DESCRIPTION OF THE PREFERRED EMBODIMENTS

The present invention will now be described with some preferred embodiments thereof and by referring to the accompanying drawings. For the purpose of easy to understand, elements that are the same in the preferred embodiments are denoted by the same reference numerals.

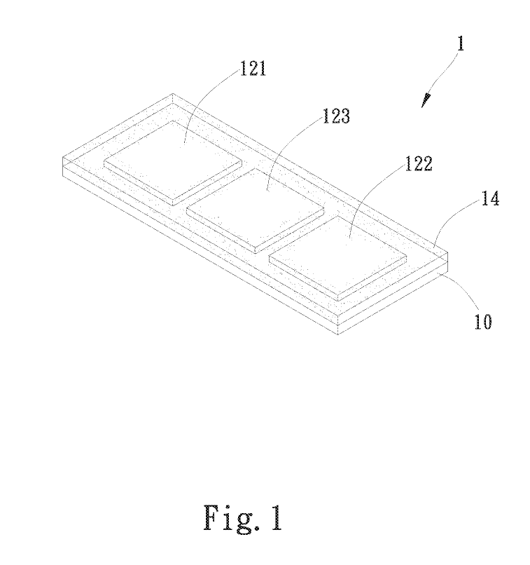

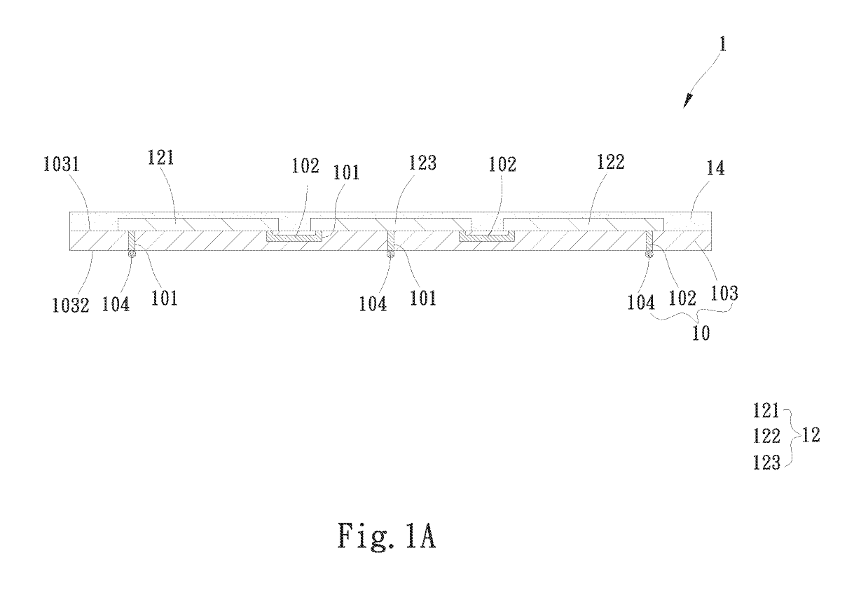

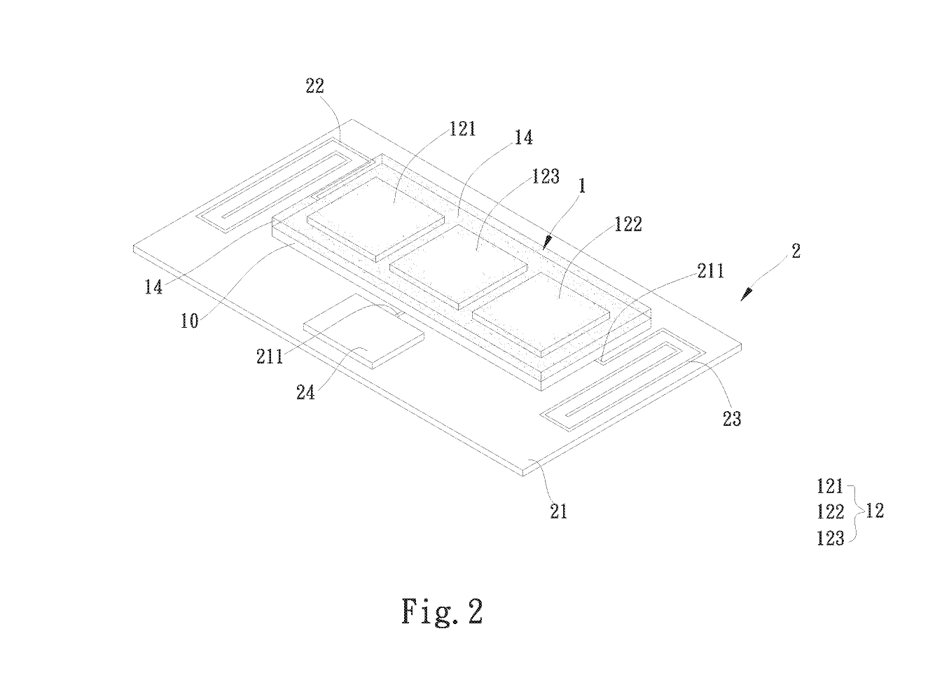

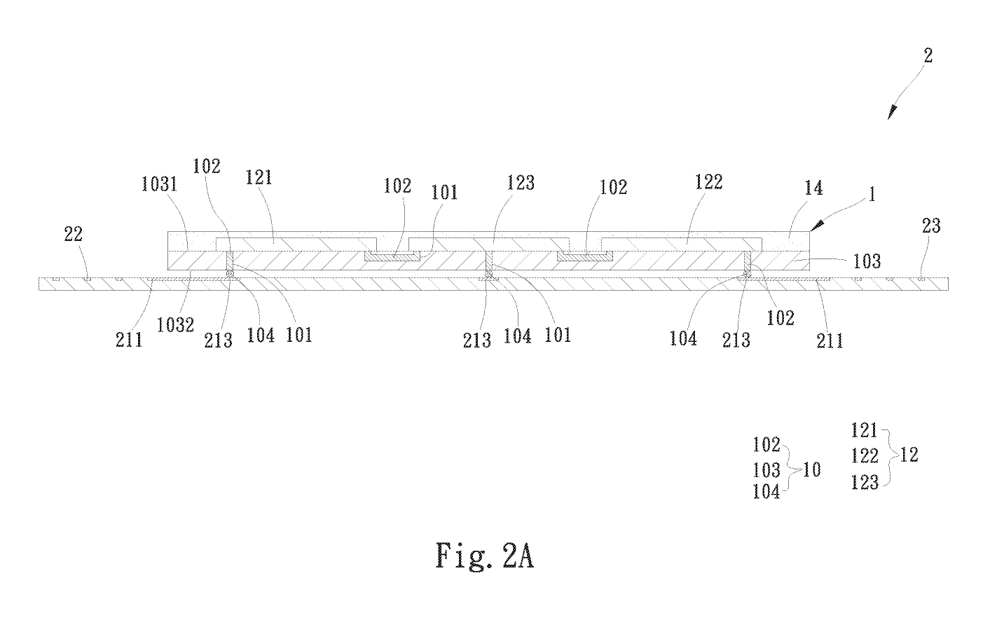

Please refer to FIGS. 1 and 1A, which are assembled perspective view and longitudinal sectional view, respectively, of a receiver and transmitter chips packaging structure 1 according to a first embodiment of the present invention. For the purpose of conciseness, the receiver and transmitter chips packaging structure 1 is also represented as the receiver/transmitter chips packaging structure 1 herein. According to the first embodiment of the present invention, the receiver/transmitter chips packaging structure 1 is designed for use in an automotive radar detector device 2 shown in FIG. 2, for example. However, in practical implementation of the present invention, the receiver/transmitter chips packaging structure 1 can also be applied to, for example, a medical scanning system. The receiver/transmitter chips packaging structure 1 includes a redistribution layer (RDL) 10, a molded encapsulation layer 14, and a chip set 12. The redistribution layer 10 includes a plurality of conductive lines 102, a dielectric layer 103, a plurality of holes 101, and a plurality of conductive elements 104. The holes 101 respectively extend from a first side 1031 (i.e. a top side) to an opposite second side 1032 (i.e. a bottom side) of the dielectric layer 103. The conductive lines 102 are metal conductive traces formed of, for example, gold, aluminum, copper, tungsten, titanium, titanium nitride (TiN), or any combination thereof and are correspondingly embedded in the holes 101 of the dielectric layer 103. The dielectric layer 103 is formed of a thin-film polymer, such as benzocyclobutene (BCB), polyimide (PI) or other organic polymers. The dielectric layer 103 can be formed of an organic material, such as polyimide (PI), or an inorganic material, such as silicon nitride, silicon oxide or other similar materials.

The conductive elements 104 are arranged on the second side (i.e. the bottom side) 1032 of the dielectric layer 103 and are respectively electrically connected to an end of a corresponding one of the conductive lines 102. The chip set 12 includes a receiver chip 121, a transmitter chip 122 and a radio-frequency (RF) processing chip 123. The receiver chip 121 is used to receive a millimeter-wave signal and the transmitter chip 122 is used to transmit a millimeter-wave signal. The receiver chip 121, the transmitter chip 122 and the RF processing chip 123 all are arranged on the first side (i.e. the top side) 1031 of the dielectric layer 103, and are respectively electrically connected to another end of a corresponding one of the conductive lines 102. The RF processing chip 123 is electrically connected to the receiver chip 121 and the transmitter chip 122 via the conductive lines 102. It is noted the receiver chip 121, the transmitter chip 122 and the RF processing chip 123 can be differently fabricated using any suitable process, such as the gallium nitride-on-silicon (GaN-on-Si) process, the gallium nitride-on-silicon carbide (GaN-on-SiC) process, the silicon-germanium complementary metal-oxide-semiconductor (SiGe CMOS) process, the gallium arsenide (GaAs) process or the radio-frequency complementary metal-oxide-semiconductor (RFCMOS) process. In the first embodiment of the present invention, the receiver chip 121 and the RF processing chip 123 are fabricated using the RFCMOS process while the transmitter chip 122 is fabricated using the SiGe CMOS process. In another operable embodiment of the present invention, the transmitter chip 122 can be differently designed and fabricated using the GaAs process while the receiver chip 121 and the RF processing chip 123 are fabricated using the RFCMOS process.

Further, the receiver chip 121 and the transmitter chip 122 can receive and transmit, respectively, a millimeter-wave signal having a center frequency of 24 GHz, 77 GHz or 120 GHz; and the signal having the center frequency of 24 GHz, 77 GHz or 120 GHz has a bandwidth ranged between −10 GHz and +10 GHz.

Please refer to FIG. 1A. In the first embodiment of the present invention, the conductive elements 104 are solder balls, such as metal balls. The conductive elements 104 are further electrically connected to the receiver chip 121, the transmitter chip 122 and the RF processing chip 123 via the conductive lines 102. The molded encapsulation layer 14 can be formed using an epoxy resin material. It is understood the aforesaid epoxy resin material is only illustrative and not intended to limit the present invention in any way. In the first embodiment of the present invention, the molded encapsulation layer 14 is formed on the first side (i.e. the top side) 1031 of the dielectric layer 103 by way of molding to cover the entire first side 1031 of the dielectric layer 103 and enclose all the receiver chip 121, the transmitter chip 122 and the RF processing chip 123 therein, so that the whole chip set 12 is encapsulated on the redistribution layer 10 by the molded encapsulation layer 14 to complete the receiver/transmitter chips packaging structure 1 of the present invention. In other words, the present invention utilizes the fan-out wafer level packaging (FOWLP) technology to integrally package multiple chips, namely, the receiver chip 121, the transmitter chip 122 and the RF processing chip 123, fabricated in different processes to form one single chip packaging structure, i.e. the receiver and transmitter chips packaging structure 1, which enables effectively upgraded performance of each of the chips. Besides, since the receiver chip 121 and the transmitter chip 122 are not integrated with any receiver antenna and transmitter antenna, respectively, it is able to enable effectively increased transmission power. For instance, in the present invention, the transmitter chip 122 can have a transmission power higher than 6 volts or from 15 to 30 volts. Portions of the molded encapsulation layer 14 that cover the outer surfaces of the receiver chip 121, the transmitter chip 122 and the RF processing chip 123 respectively have a thickness from 100 to 700 μm. By covering the chip set 12 with the molded encapsulation layer 14, the chip set 12 can have a flat and smooth outer surface.

In an operable embodiment, the conductive elements 104 can be differently designed to be metal solder pads, such as copper or gold solder pads.

Therefore, with the above arrangements, the receiver/transmitter chips packaging structure 1 according to the first embodiment of the present invention can provide the effects of upgraded transmission efficiency and chip performance as well as increased transmission power.

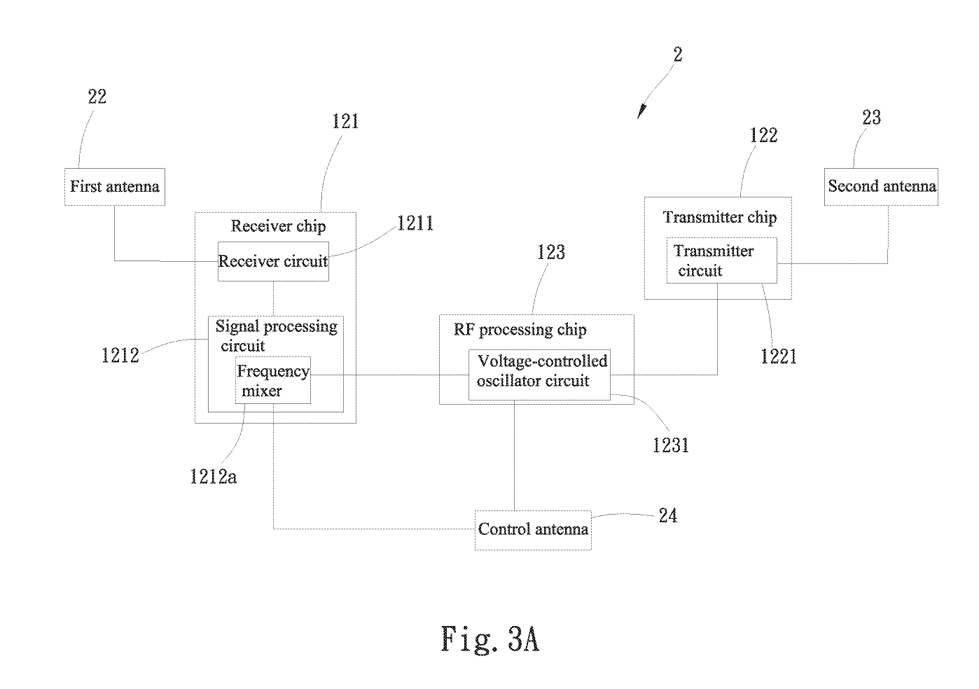

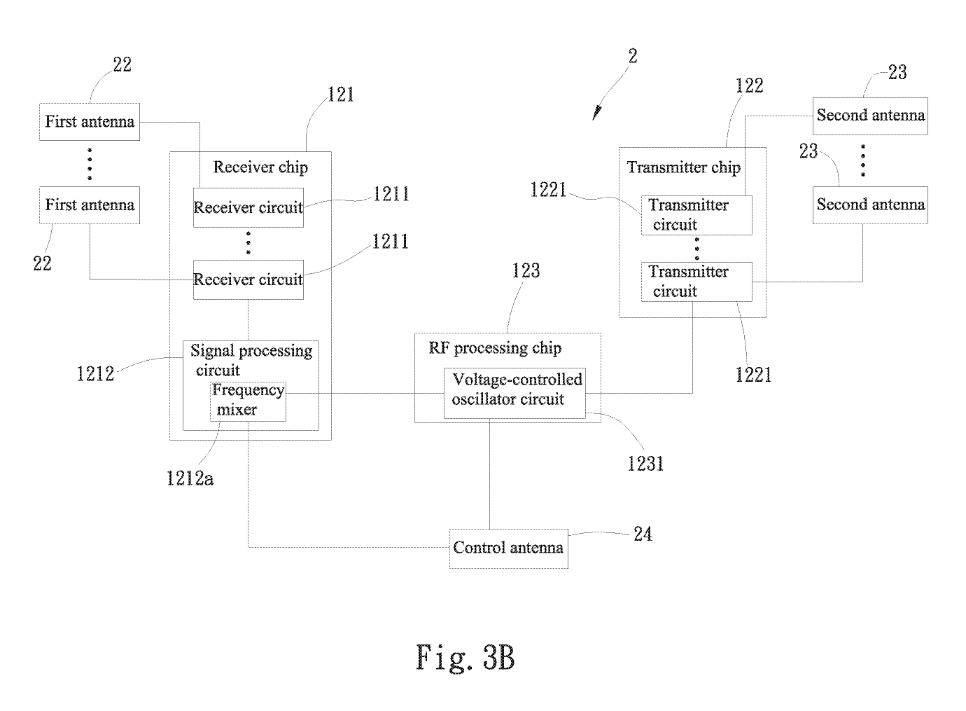

Please refer to FIGS. 2 and 2A, which are assembled perspective view and longitudinal sectional view, respectively, of an automotive radar detector device 2 according to a second embodiment of the present invention; and to FIGS. 3A and 3B, which are block diagrams showing two possible arrangements of the automotive radar detector device 2 according to the second embodiment of the present invention. As shown, the automotive radar detector device 2 includes a receiver/transmitter chips packaging structure 1, a substrate 21 and a control chip 24. The receiver/transmitter chips packaging structure 1 included in the second embodiment of the present invention is structurally and functionally identical to that in the first embodiment of the present invention and is therefore not repeatedly described herein. In the second embodiment, the substrate 21 is illustrated as a printed circuit board, and can be an FR-4 substrate made of fiberglass epoxy resin, a polyphenylene oxide (PPO) substrate, or a polytetrafluoroethylene (PTFE) substrate. In an operable embodiment, the substrate 21 can be a glass substrate. In the second embodiment of the present invention, the conductive elements 104 on the second side 1032 of the dielectric layer 103 of the redistribution layer 10 are illustrated as solder balls, such as metal balls, which are arranged on the second side 1032 of the dielectric layer 103 by ball grid array (BGA) without being particularly limited thereto.

The substrate 21 is located at one side of the redistribution layer 10. In the second embodiment of the present invention, the substrate 21 is located beneath the second side 1032 of the dielectric layer 103 of the redistribution layer 10. On the substrate 21, there are provided at least one first antenna 22, at least one second antenna 23, a plurality of conductive wirings 211 and a plurality of contacts 213. In the second embodiment, the contacts 213 are solder pads formed on one side of the substrate 21 and electrically connected to the conductive elements 104 on the redistribution layer 10 while the conductive elements 104 are located between the dielectric layer 103 and the substrate 21. The conductive wirings 211 are metal wirings formed of copper or gold, and are provided in the substrate 21 to electrically connect to the contacts 213. In the second embodiment, the first and the second antenna 22, 23 are illustrated as array antennas provided on one side of the substrate 21 facing toward the dielectric layer 103 to electrically connect to the receiver chip 121 and the transmitter chip 122, respectively, via the conductive wirings 211 and the contacts 213. The contacts 213 connected to the first antenna 22 are in direct contact with the conductive elements 104 connected to the receiver chip 121, so that a signal connection or an electrical connection is formed between the first antenna 22 and the receiver chip 121. Similarly, the contacts 213 connected to the second antenna 23 are in direct contact with the conductive elements 104 connected to the transmitter chip 122, so that a signal connection or an electrical connection is formed between the second antenna 23 and the transmitter chip 122.

The control chip 24 can be a microprocessor control unit (MCU), a central processing unit (CPU) or a digital signal processor (DSP), and is arranged on one side of the substrate 21 to electrically connect to the receiver chip 121 and the RF processing chip 123 via the conductive wirings 211 and the contacts 213. In the second embodiment, the contacts 213 connected to the control chip 24 is in direct contact with the conductive elements 104 connected to the receiver chip 121 and the RF processing chip 123, so that a signal connection or an electrical connection is formed between the control chip 24 and the receiver and RF processing chips 121, 123. Further, the receiver chip 121 has at least one receiver circuit 1211 and a signal processing circuit 1212. In the illustrated second embodiment, as shown in FIG. 3A, there are one receiver circuit 1211 and one signal processing circuit 1212 correspondingly connected to one first antenna 22; and the signal processing circuit 1212 is electrically connected to the receiver circuit 1211 and the RF processing chip 123. The signal processing circuit 1212 includes a frequency mixer 1212a, which serves as a down-converter in the second embodiment but is not particularly limited thereto. The frequency mixer 1212a is used to process a receiving signal (i.e. a reflected signal from an external object) received by the first antenna 22 and transmitted to the receiver circuit 1211, and to process a local oscillator signal (LO) transmitted by the RF processing chip 123. The frequency mixer 1212a mixes the frequencies of the receiving signal and the local oscillator signal, and performs a down conversion of the mixed signal to generate a signal receiving result, i.e. a mid-frequency signal, to the control chip 24, so that the control chip 24 can determine, based on the receiving signal result, the displacement and speed of and the distance from the external object to achieve the function of a radar detector.

The transmitter chip 122 has at least one transmitter circuit 1221. In the illustrated second embodiment as shown in FIG. 3A, there is one transmitter circuit 1221 correspondingly connected to one second antenna 23. The RF processing chip 123 has a voltage-controlled oscillator circuit 1231 electrically connected to the frequency mixer 1212a of the signal processing circuit 1212 and to the transmitter circuit 1221 for providing the local oscillator signal to the signal processing circuit 1212 and providing a detection signal. The control chip 24 controls the voltage-controlled oscillator circuit 1231 to output the detection signal to the transmitter circuit 1221, allowing the transmitter circuit 1221 to transmit the detection signal via the second antenna 23. The aforesaid detection signal and receiving signal are also millimeter waves. In practical implementation of the present invention, the control chip 24 is electrically connected to a controller area network bus (CAN BUS) system (not shown), and the CAN BUS system can control a car to slow down or to blink a warning light according to a notice signal transmitted by the control chip 24 to warn a driver of, for example, a too close distance between the car and an external object.

Further, in the second embodiment, the first antenna 22, the second antenna 23, the receiver circuit 1211 and the transmitter circuit 1221 are respectively not necessarily limited to one in number. However, the number of the first antennas 22 and of the second antennas 23 are corresponding to that of the receiver circuits 1211 and of the transmitter circuits 1221, respectively. In practical implementation of the present invention, the actual number of the first antennas 22, of the second antennas 23, of the receiver circuits 1211 and of the transmitter circuits 1221 can be changed in advance according to the required precision, range of detection and mounting position of the millimeter-wave radar detector device 2. For example, as shown in FIG. 3A, there are only one receiver circuit 1211 and one transmitter circuit 1221 as well as one first antenna 22 and one second antenna 23 to constitute one set of automotive radar detector device 2. On the other hand, as shown in FIG. 3B, there are three receiver circuits 1211 and three transmitter circuits 1221 as well as three first antennas 22 and three second antennas 23 to constitute three sets of automotive radar detector devices 2. Similarly, the number of the receiver circuits 1211 and of the transmitter circuits 1221 as well as the number of the first antennas 22 and of the second antennas 23 can be correspondingly increased or decreased.

In the second embodiment, the first antenna 22 and the second antenna 23 can receive and transmit, respectively, a millimeter-wave signal having a center frequency of 24 GHz, 77 GHz or 120 GHz; and the signal having the center frequency of 24 GHz, 77 GHz or 120 GHz has a bandwidth ranged between −10 GHz and +10 GHz. Further, the receiving signal and the detection signal are millimeter-wave signals.

Therefore, with the above arrangements, the automotive radar detector device 2 according to the second embodiment of the present invention can provide the effects of upgraded transmission efficiency and chip performance as well as increased transmission power.

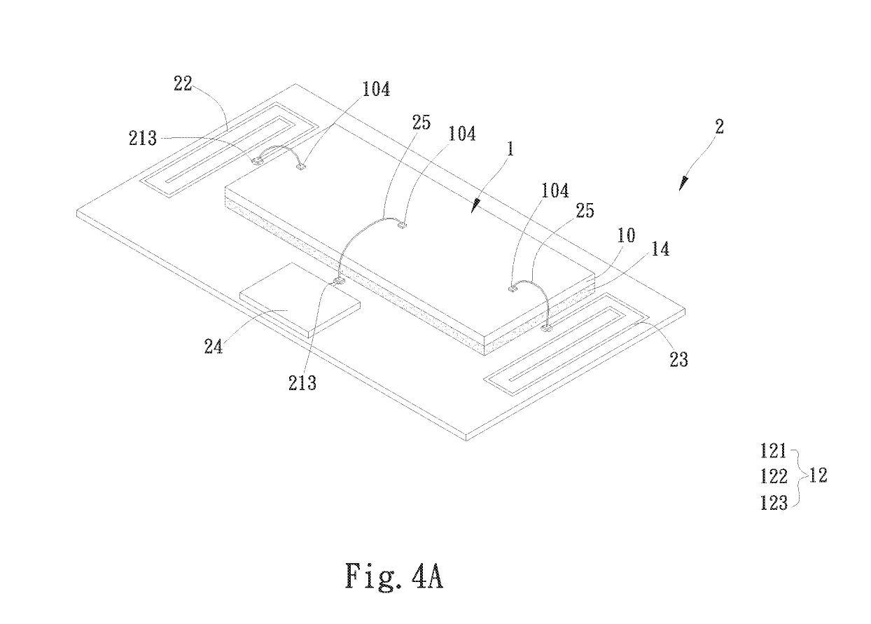

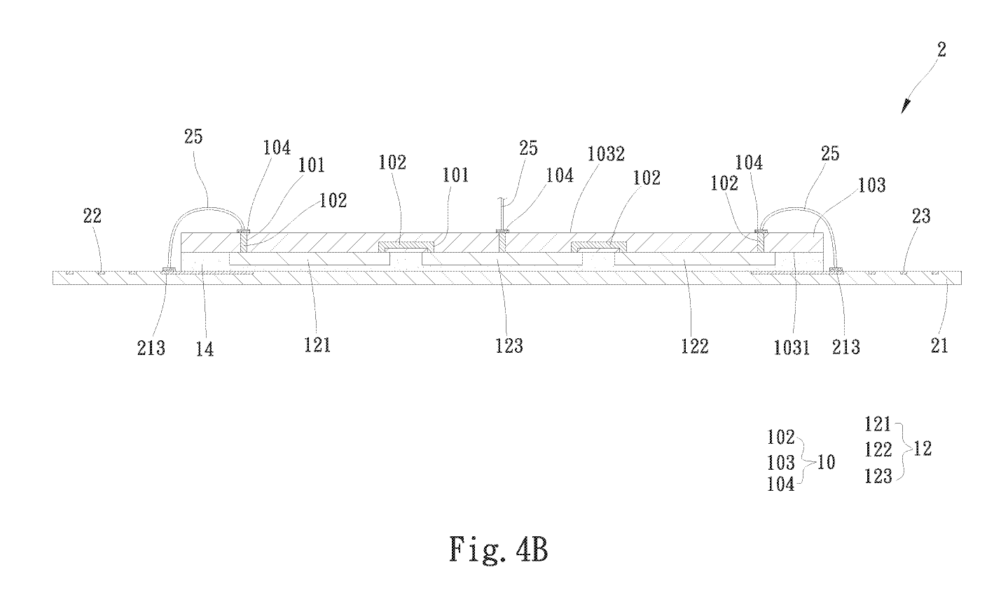

Please refer to FIGS. 4A and 4B, which are assembled perspective view and longitudinal sectional view, respectively, of an automotive radar detector device 2 according to a third embodiment of the present invention. The automotive radar detector device 2 in the third embodiment is generally structurally and functionally similar to that in the second embodiment, but has a substrate 21 located beneath the molded encapsulation layer 14 instead of beneath the redistribution layer 10 and has a plurality of conductive elements 104 in the form of solder pads instead of solder balls.

In the third embodiment, the substrate 21 is located beneath the molded encapsulation layer 14 with one side facing toward and in direct contact with the molded encapsulation layer 14, and the conductive elements 104 on the second side 1032 of the dielectric layer 103 are electrically connected to the contacts 213 via a plurality of bonding wires 25. In the third embodiment, the contacts 213 connected to the first antenna 22 are further connected via the bonding wires 25 to the conductive elements 104 connected to the receiver chip 121, so that a signal connection or an electrical connection is formed between the first antenna 22 and the receiver chip 121; the contacts 213 connected to the control chip 24 are further connected via the bonding wires 25 to the conductive elements 104 connected to the receiver chip 121 and the RF processing chip 123, so that a signal connection or an electrical connection is formed between the control chip 24 and the receiver and RF processing chips 121, 123; and the contacts 213 connected to the second antenna 23 are further connected via one of the bonding wires 25 to the conductive elements 104 connected to the transmitter chip 122, so that a signal connection or an electrical connection is formed between the second antenna 23 and the transmitter chip 122. Therefore, with the above arrangements, the automotive radar detector device 2 according to the third embodiment of the present invention can provide the effects of upgraded transmission efficiency and chip performance as well as increased transmission power.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A receiver and transmitter chips packaging structure, comprising:
a redistribution layer including a plurality of conductive lines, a dielectric layer and a plurality of conductive elements; the conductive lines being embedded in the dielectric layer; the dielectric layer having a first side and an opposite second side; and the conductive elements being arranged on the second side of the dielectric layer and being respectively electrically connected to an end of a corresponding one of the conductive lines;
a chip set including a receiver chip, a transmitter chip and a radio-frequency (RF) processing chip; the receiver chip, the transmitter chip and the RF processing chip being arranged on the first side of the dielectric layer and being respectively electrically connected to another end of a corresponding one of the conductive lines; and the RF processing chip being electrically connected to the receiver chip and the transmitter chip via the conductive lines; and
a molded encapsulation layer being formed on the first side of the dielectric layer to enclose the receiver chip, the transmitter chip and the RF processing chip therein.

2. The receiver and transmitter chips packaging structure as claimed in claim 1, wherein the redistribution layer has a plurality of holes formed thereon to respectively extend from the first side to the second side of the dielectric layer; and the conductive lines being correspondingly embedded in the holes of the dielectric layer.

3. The receiver and transmitter chips packaging structure as claimed in claim 2, wherein the conductive elements are further connected to the receiver chip, the transmitter chip and the RF processing chip via the conductive lines, such that an electrical connection is formed between each of the conductive elements and a corresponding one of the receiver chip, the transmitter chip and the RF processing chip.

4. The receiver and transmitter chips packaging structure as claimed in claim 1, wherein portions of the molded encapsulation layer that cover the outer surfaces of the receiver chip, the transmitter chip and the RF processing chip respectively have a thickness from 100 to 700 μm.

5. The receiver and transmitter chips packaging structure as claimed in claim 4, wherein the conductive elements are selected from the group consisting of solder pads and solder balls, and the conductive lines are metal conductive traces.

6. The receiver and transmitter chips packaging structure as claimed in claim 1, wherein the receiver chip and the transmitter chip can receive and transmit, respectively, a millimeter-wave signal having a center frequency of 24 GHz, 77 GHz or 120 GHz; and the signal having the center frequency of 24 GHz, 77 GHz or 120 GHz having a bandwidth ranged between −10 GHz and +10 GHz.

7. An automotive radar detector device, comprising:
a receiver and transmitter chips packaging structure including:
a redistribution layer including a plurality of conductive lines, a dielectric layer and a plurality of conductive elements; the conductive lines being embedded in the dielectric layer; the dielectric layer having a first side and an opposite second side; and the conductive elements being arranged on the second side of the dielectric layer and being respectively electrically connected to an end of a corresponding one of the conductive lines;
a chip set including a receiver chip, a transmitter chip and a radio-frequency (RF) processing chip; the receiver chip, the transmitter chip and the RF processing chip being arranged on the first side of the dielectric layer and being respectively electrically connected to another end of a corresponding one of the conductive lines; and the RF processing chip being electrically connected to the receiver chip and the transmitter chip via the conductive lines; and
a molded encapsulation layer being formed on the first side of the dielectric layer and enclosing the receiver chip, the transmitter chip and the RF processing chip therein;
a substrate being selectively arranged on one side of the redistribution layer or the molded encapsulation layer, and having at least one first antenna, at least one second antenna, a plurality of conductive wirings and a plurality of contacts provided thereon to electrically connect to the conductive elements on the redistribution layer; the conductive wirings being embedded in the substrate to electrically connect to the contacts that are formed on one side of the substrate; and the first and the second antenna being provided on one side of the substrate to electrically connect to the receiver chip and the transmitter chip via the conductive wirings and the contacts; and
a control chip being arranged on one side of the substrate to electrically connect to the receiver chip and the RF processing chip via the conductive wirings and the contacts.

8. The automotive radar detector device as claimed in claim 7, wherein the redistribution layer has a plurality of holes formed thereon to respectively extend from the first side to the second side of the dielectric layer; and the conductive lines being correspondingly embedded in the holes of the dielectric layer.

9. The automotive radar detector device as claimed in claim 8, wherein the substrate is arranged on one side of the redistribution layer and is located beneath the redistribution layer, and the conductive elements arranged on the second side of the dielectric layer are facing toward and in direct contact with the contacts to thereby electrically connect to the contacts.

10. The automotive radar detector device as claimed in claim 9, wherein the conductive elements are further connected to the receiver chip, the transmitter chip and the RF processing chip via the conductive lines, such that an electrical connection is formed between each of the conductive elements and a corresponding one of the receiver chip, the transmitter chip and the RF processing chip.

11. The automotive radar detector device as claimed in claim 10, wherein the contacts connected to the first antenna are in direct contact with the conductive elements connected to the receiver chip, such that a signal connection is formed between the first antenna and the receiver chip; the contacts connected to the control chip are in direct contact with the conductive elements connected to the receiver chip and the RF processing chip, such that a signal connection is formed between the control chip and the receiver and RF processing chips; and the contacts connected to the second antenna are in direct contact with the conductive elements connected to the transmitter chip, such that a signal connection is formed between the second antenna and the transmitter chip.

12. The automotive radar detector device as claimed in claim 8, wherein the substrate is arranged on one side of the molded encapsulation layer and is located beneath the molded encapsulation layer; and the conductive elements arranged on the second side of the dielectric layer are electrically connected to the contacts via a plurality of bonding wires.

13. The automotive radar detector device as claimed in claim 12, wherein the conductive elements are further connected to the receiver chip, the transmitter chip and the RF processing chip via the conductive lines, such that an electrical connection is formed between each of the conductive elements and a corresponding one of the receiver chip, the transmitter chip and the RF processing chip.

14. The automotive radar detector device as claimed in claim 13, wherein the contacts connected to the first antenna are further connected via the bonding wires to the conductive elements that are connected to the receiver chip, such that a signal connection is formed between the first antenna and the receiver chip; the contacts connected to the control chip are further connected via the bonding wires to the conductive elements that are connected to the receiver chip and the RF processing chip, such that a signal connection is formed between the control chip and the receiver and RF processing chips; and the contacts connected to the second antenna are further connected via one of the bonding wires to the conductive elements that are connected to the transmitter chip, such that a signal connection is formed between the second antenna and the transmitter chip.

15. The automotive radar detector device as claimed in claim 7, wherein the substrate is selected from the group consisting of a printed circuit board and a glass substrate; and the control chip is selected from the group consisting of a microprocessor control unit (MCU) and a central processing unit (CPU).

16. The automotive radar detector device as claimed in claim 7, wherein portions of the molded encapsulation layer that cover the outer surfaces of the receiver chip, the transmitter chip and the RF processing chip respectively have a thickness from 100 to 700 μm.

17. The automotive radar detector device as claimed in claim 7, wherein the conductive elements are selected from the group consisting of solder pads and solder balls, and the conductive lines are metal conductive traces.

18. The automotive radar detector device as claimed in claim 7, wherein the receiver chip has at least one receiver circuit and a signal processing circuit; and the signal processing circuit being electrically connected to the at least one receiver circuit and the RF processing chip to process a receiving signal received by the first antenna and transmitted to the at least one receiver circuit and a local oscillator signal transmitted by the RF processing chip.

19. The automotive radar detector device as claimed in claim 18, wherein the RF processing chip has a voltage-controlled oscillator circuit electrically connected to the signal processing circuit for providing the local oscillator signal to the signal processing circuit and providing a detection signal; the transmitter chip having at least one transmitter circuit electrically connected to the voltage-controlled oscillator circuit for transmitting the detection signal via the second antenna; and the control chip being used to receive a signal receiving result generated by the signal processing circuit after processing of the receiving signal and to control the voltage-controlled oscillator circuit to output the detection signal to the transmitter circuit.

20. The automotive radar detector device as claimed in claim 19, wherein the first antenna and the second antenna can receive and transmit, respectively, a millimeter-wave signal having a center frequency of 24 GHz, 77 GHz or 120 GHz; and the signal having the center frequency of 24 GHz, 77 GHz or 120 GHz having a bandwidth ranged between −10 GHz and +10 GHz; and wherein the receiving signal and the detection signal are millimeter-wave signals.
